(19) United States
(12) Patent Application Publication
(10) Pub. No.: US 2020/0168751 A1
(43) Pub. Date: May 28, 2020

(54) SOLAR CELL AND SOLAR CELL MODULE

(71) Applicant: PANASONIC CORPORATION, Osaka (JP)

(72) Inventor: Manabu SASAKI, Mie (JP)

(73) Assignees: PANASONIC CORPORATION, Osaka (JP); PANASONIC CORPORATION, Osaka (JP)

(21) Appl. No.: 16/688,762

(22) Filed: Nov. 19, 2019

(30) Foreign Application Priority Data
Nov. 22, 2018 (JP) 2018-218866

(51) Int. Cl. H01L 31/0376; H01L 31/0236; H01L 31/075; H01L 31/0224; H01L 31/20

(52) U.S. Cl. CPC H01L 31/03762; H01L 31/02363; H01L 31/202; H01L 31/022425; H01L 31/075

(57) ABSTRACT

A solar cell includes a semiconductor substrate having a first principal surface at an angle of at least 1 degree and at most 45 degrees relative to a plane orientation. The first principal surface is in a shape of a rectangle having a long axis and a short axis orthogonal to each other.

### CROSS REFERENCE TO RELATED APPLICATION

This application claims the benefit of priority of Japanese Patent Application Number 2018-218866, filed on Nov. 22, 2018, the entire content of which is hereby incorporated by reference.

### TECHNICAL FIELD

The present disclosure relates to a solar cell and a solar cell module.

### BACKGROUND ART

A solar cell has been expected to be a new energy source since the solar cell can directly convert clean and unlimited sunlight into electric power.

### CITATION LIST

### Patent Literature

Patent Literature 1: Japanese Unexamined Patent Application Publication No. 2010-34160

### SUMMARY

### Technical Problem

There has been a demand for further improvement in the power generation characteristic of a solar cell. An aspect of the present invention provides a solar cell and a solar cell module each having an improved power generation characteristic.

### Solution to Problem

A solar cell according to an aspect of the present invention includes: a semiconductor substrate having a first principal surface at an angle of at least 1 degree and at most 45 degrees relative to a plane orientation, wherein the first principal surface is in a shape of a rectangle having a long axis and a short axis orthogonal to each other. In addition, a solar cell module according to an aspect of the present invention includes the solar cell described above.

### Advantageous Effects

According to an aspect of the present invention, it is possible to provide a solar cell and a solar cell module each having an improved power generation characteristic.

### BRIEF DESCRIPTION OF THE DRAWINGS

The figures depict one or more implementations in accordance with the present teaching, by way of examples only, not by way of limitations. In the figures, like reference numerals refer to the same or similar elements.

FIG. 1 is a cross sectional view illustrating a structure of a solar cell according to an embodiment.

FIG. 2 is a plan view illustrating a structure of a light receiving surface-side of the solar cell according to the embodiment.

FIG. 3 is a plan view illustrating a structure of a light receiving surface-side of a semiconductor wafer according to the embodiment.

FIG. 4 is a cross sectional view illustrating the structure of the semiconductor wafer according to the embodiment.

FIG. 5 is a cross sectional view illustrating the structure of the semiconductor wafer according to the embodiment where a texture structure according to the embodiment is formed on each of principal surfaces of the semiconductor wafer.

FIG. 6 is a plan view illustrating a light receiving surface-side of the texture structure according to the embodiment.

FIG. 7 is a flowchart illustrating a manufacturing method of the solar cell according to the embodiment.

FIG. 8 is a perspective view illustrating an appearance of a semiconductor ingot according to the embodiment.

FIG. 9 is a diagram illustrating a process of slicing the semiconductor ingot according to the embodiment.

FIG. 10 is a diagram illustrating a process of slicing the semiconductor ingot according to a conventional example.

FIG. 11 is a diagram illustrating a process of slicing a semiconductor ingot according to a variation of the embodiment.

FIG. 12 is a cross sectional view illustrating a structure of a solar cell module according to the embodiment.

FIG. 13 is a plan view illustrating a structure of a light receiving surface-side of the solar cell module according to the embodiment.

### DETAILED DESCRIPTION

Hereinafter, a solar cell according to embodiments and a solar cell module according to the embodiments will be described in detail with reference to the drawings. The embodiments described below each illustrate a specific example of an aspect of the present invention. Therefore, the numerical values, shapes, materials, structural elements, the arrangement and the connection of the structural elements, and the processing order of the steps etc. illustrated in the following embodiments are not intended to limit an aspect of the present invention. Consequently, among the structural elements in the following embodiments, those not recited in any of the independent claims representing the most generic concepts are described as optional structural elements.

The drawings are schematic diagrams and do not necessarily provide strictly accurate illustrations. Throughout the drawings, the same numeral is given to substantially the same structural component.

In this specification, the “light receiving surface” indicates a surface through which a greater amount of light is allowed to pass to enter the solar cell, compared to the “back surface” of a solar cell which is a surface opposite to the light receiving surface of the solar cell. Note that the above also includes the case in which absolutely no light enters the solar cell from the “back surface”-side. In addition, the “light receiving surface” of a solar cell module indicates a surface through which the light of the “light receiving surface” of the solar cell is allowed to pass, and the “back surface” of the solar cell module indicates a surface opposite to the light receiving surface of the solar cell module. In addition, a statement such as “providing a second component above/below a first component” is not intended to merely indicate the case in which the first and the second components are provided in contact with each other, unless a limitation is particularly imposed on the statement. That is, the statement includes the case in which there is another component present between the first and the second components. In addition, the expression “substantially XXX” is intended to include that which is considered to be practically XXX. Taking “substantially the same” as an example, the expression is intended to include, not only that which is perfectly the same, but also that which is considered to be practically the same.

### Embodiment

### [1. Configuration of Solar Cell According to Embodiment]

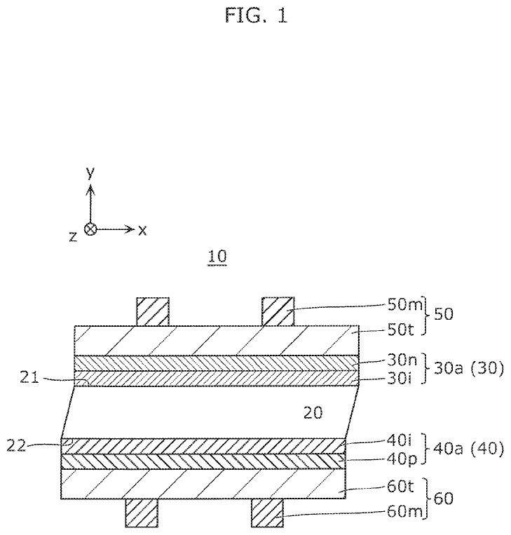

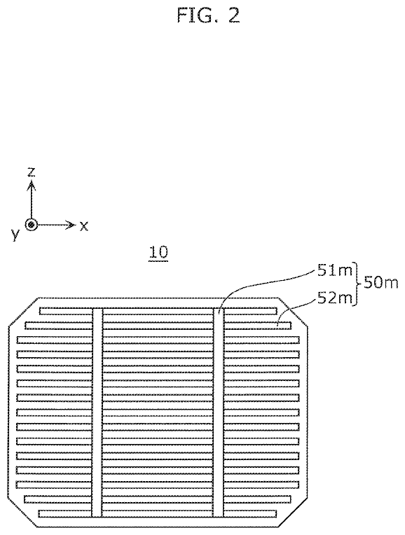

A general configuration of a solar cell 10 according to the embodiment will be described with reference to FIG. 1 through FIG. 6. FIG. 1 is a cross sectional view illustrating a structure of the solar cell 10 according to the embodiment. FIG. 2 is a plan view illustrating a structure of the light receiving surface-side of the solar cell 10 according to the embodiment.

The solar cell 10 is provided with a semiconductor substrate 20. The semiconductor substrate 20 has a first principal surface 21 and a second principal surface 22 which are disposed at mutually opposing positions. The embodiment describes an example in which the first principal surface 21 is the light receiving surface-side surface of the solar cell 10, and the second principal surface 22 is the back surface-side surface of the solar cell 10. The semiconductor substrate 20 generates photocarriers by receiving light. Here, the photocarriers are electrons and holes which are generated by the light absorbed into the semiconductor substrate 20. The semiconductor substrate 20 has a first conductivity type of either n-type or p-type. In order to improve the efficiency of utilizing incident light, the first principal surface 21 of the semiconductor substrate 20 may have a texture structure which includes a plurality of bumpy portions. On the other hand, the second principal surface 22 of the semiconductor substrate 20 may have the texture structure which includes the plurality of bumpy portions, or may have a flat surface instead of the texture structure. The height of the texture structure is, for example, 0.5 μm to 25 μm, and preferably 2 μm to 8 μm.

As the semiconductor substrate 20, a crystalline silicon substrate, such as a monocrystalline silicon substrate or a polycrystalline silicon substrate, can be used. In addition, a substrate other than the crystalline silicon substrate can also be used as the semiconductor substrate 20. For example, a typical semiconductor substrate, such as a germanium (Ge) semiconductor substrate, a IV-IV compound semiconductor substrate typified by silicon carbide (SiC) and silicon germanium (SiGe), and a III-V compound semiconductor substrate typified by gallium arsenide (GaAs), gallium nitride (GaN), and indium phosphide (InP), can be used.

The embodiment describes an example of the case in which (i) a monocrystalline silicon substrate is used as the semiconductor substrate 20, (ii) the first conductivity type is n-type, and (iii) a second conductivity type which is opposite to the first conductivity type is p-type. The thickness of the semiconductor substrate 20 is, for example, 30 μm to 300 μm, and preferably about 50 μm to 150 μm. In addition, the semiconductor substrate 20 includes, as an n-type impurity, a dopant, such as phosphorus (P), arsenic (As), or antimony (Sb), for example. The concentration of the first conductivity type impurity in the semiconductor substrate 20 is, for example, 1×10¹⁴ cm⁻³ to 1×10¹⁷ cm⁻³, and preferably 5×10¹⁴ cm⁻³ to 5×10¹⁵ cm⁻³.

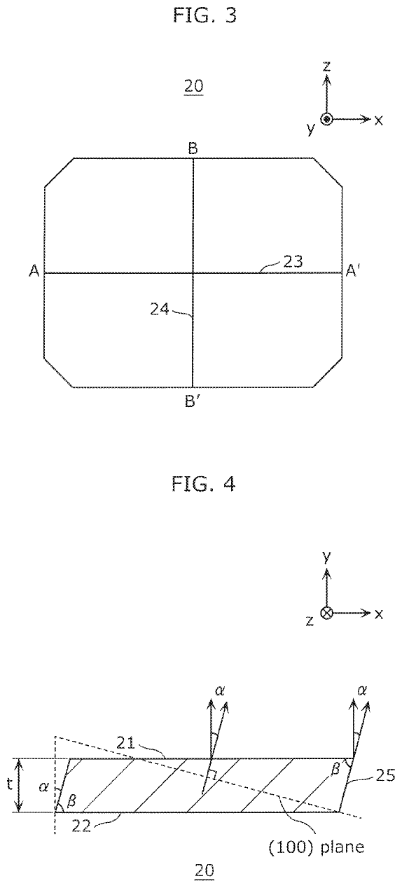

FIG. 3 is a plan view illustrating a structure of the light receiving surface-side of a semiconductor wafer (the semiconductor substrate 20) according to the embodiment. FIG. 4 is a cross sectional view illustrating the structure of the semiconductor wafer (the semiconductor substrate 20) according to the embodiment. As illustrated in FIG. 3, the first principal surface 21 of the semiconductor substrate 20 is in the shape of a rectangle which has a long axis 23 and a short axis 24. In addition, the principal surface 21 has an octagon shape formed out of the rectangle which has the long axis 23 and the short axis 24, and of which the four corners are obliquely cut. Note that these obliquely cut corners may be rounded. Furthermore, the obliquely cut corners may be in any shape other than the aforementioned shapes. For example, the obliquely cut corners each may be in the shape of a lozenge or an oval. The first principal surface 21 of the semiconductor substrate 20 is axially symmetric with respect to the long axis 23 and the short axis 24. In addition, the long axis 23 is longer than the short axis 24. Furthermore, the long axis 23 and the short axis 24 are mutually orthogonal. As illustrated in FIG. 3, the principal surface 21 of the semiconductor substrate 20 has an octagon shape formed out of the rectangle which has the long axis 23 and the short axis 24, and of which the four corners are obliquely cut. The long axis 23 is a line segment from A to A′, and the short axis 24 is a line segment from B to B′. The first principal surface 21 of the semiconductor substrate 20 and the second principal surface 22 of the semiconductor substrate 20 each are in the shape of a rectangle, for example. The rectangle includes a rectangle, an octagon formed out of the rectangle of which the four corners are obliquely cut, and the octagon with rounded cut-outs.

In addition, as illustrated in FIG. 4, the first principal surface 21 of the semiconductor substrate 20 is slanted by the angle α relative to a (100) plane. For example, the angle α is at least 1 degree and at most 45 degrees, and preferably, at least 2 degrees and at most 20 degrees. More preferably, the angle α is at least 3 degrees and at most 10 degrees.

Furthermore, a cross section which includes the direction normal to the first principal surface 21 of the semiconductor substrate 20 and the direction of the long axis 23 of the semiconductor substrate 20 is in the shape of a parallelogram. The angle β formed by the first principal surface 21 of the semiconductor substrate 20 and a first side face 25 of the semiconductor substrate 20 can be expressed by β=(90−α). In addition, the length of the first side face 25 from the first principal surface 21 to the second principal surface 22 is a value obtained by dividing the thickness t of the semiconductor substrate 20 by cos α. The length is greater than the thickness t of the semiconductor substrate 20. Since this increases the length of the first side face 25 from the first principal surface 21 to the second principal surface 22, it is possible to reduce, at the first side face 25 of the semiconductor substrate 20, the flow of a leakage current between a first semiconductor layer 30 which is disposed on the first principal surface 21-side and a second semiconductor layer 40 which is disposed on the second principal surface 22-side. Consequently, it is possible to improve the power generation characteristic of the solar cell 10. Note that the cross section which includes the direction normal to the first principal surface 21 of the semiconductor substrate 20 and the direction of the short axis 24 of the semiconductor substrate 20 is in the shape of a rectangle.

Note that the first principal surface 21 of the semiconductor substrate 20 may be slanted by the angle α relative to one plane orientation. The aforementioned one plane orientation is, for example, a (100) plane, a (110) plane, a (111) plane, a (211) plane, a (311) plane, a (411) plane, a (511) plane, and a (611) plane.

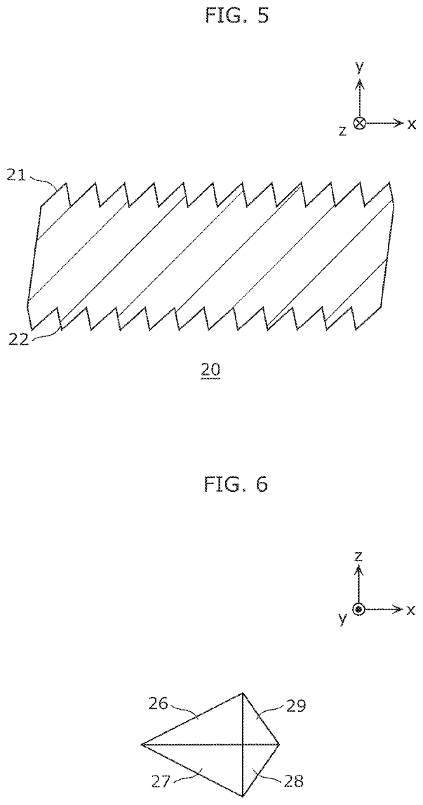

FIG. 5 is a cross sectional view illustrating the structure of the semiconductor wafer (the semiconductor substrate 20) according to the embodiment where a texture structure according to the embodiment is formed on each of principal surfaces of the semiconductor wafer. In addition, FIG. 6 is a plan view illustrating a light receiving surface-side of the texture structure according to the embodiment. As illustrated in FIG. 5, the semiconductor substrate 20 has a texture structure formed on each of the first principal surface 21 and the second principal surface 22. For example, as illustrated in FIG. 6, the texture structure of the semiconductor substrate 20 is a ridged structure in which quadrangular pyramids each having pyramidal surfaces 26, 27, 28, and 29 which are (111) planes are two-dimensionally arrayed on the first principal surface 21. As illustrated in FIG. 6, when a quadrangular pyramid on the first principal surface 21-side is viewed from the above, the area of each of the first pyramidal surfaces 26 and 27 of the quadrangular pyramid is larger than the area of each of the second pyramidal surfaces 28 and 29, and the second pyramidal surfaces 28 and 29 are disposed more in the positive direction of the x axis compared to where the first pyramidal surfaces 26 and 27 are disposed. Since the area of each of the two first pyramidal surfaces 26 and 27 of a quadrangular pyramid is larger than the area of each of the two second pyramidal surfaces 28 and 29 of the quadrangular pyramid as described above, light which enters the solar cell 10 can be complexly reflected and diffracted, compared to the case in which a quadrangular pyramid formed of four pyramidal surfaces having the same area is used, thereby improving the efficiency of utilizing the light which enters the solar cell 10. Consequently, it is possible to improve the power generation characteristic of the solar cell 10.

In contrast, when a quadrangular pyramid on the second principal surface 22-side is viewed from the above, the pyramidal surfaces 28 and 29 each having a larger area are disposed more in the negative direction of the x-axis compared to where the pyramidal surfaces 26 and 27 each having a smaller area are disposed. Since the texture structures which reflect and diffract light in mutually opposite directions are formed each on the first principal surface 21 of the semiconductor substrate 20 and the second principal surface 22 of the semiconductor substrate 20 as described above, light which enters the solar cell 10 can be more complexly reflected and diffracted, thereby further improving the efficiency of utilizing the light which enters the solar cell 10. Consequently, it is possible to further improve the power generation characteristic of the solar cell 10.

As illustrated in FIG. 1, the first semiconductor layer 30 of the first conductivity type which is a conductivity type same as the conductivity type that the semiconductor substrate 20 has is provided above the entirety of, or above substantially the entirety of the first principal surface 21 of the semiconductor substrate 20. The first semiconductor layer 30 has a function of reducing carrier recombination at and in the vicinity of the joining interface between the first semiconductor layer 30 and the semiconductor substrate 20. In this embodiment, an amorphous silicon layer 30a is used as the first semiconductor layer 30. In addition, the amorphous silicon layer 30a has a stacked structure in which an intrinsic amorphous silicon layer 30i and a first conductivity type amorphous silicon layer 30n of the first conductivity type are stacked from the first principal surface 21 of the semiconductor substrate 20 in the stated order. The intrinsic amorphous silicon layer 30i is provided above (the positive direction of the y axis) the first principal surface 21 of the semiconductor substrate 20. The first conductivity type amorphous silicon layer 30n is provided above (the positive direction of the y axis) the intrinsic amorphous silicon layer 30i. In this embodiment, the semiconductor substrate 20 and the first semiconductor layer 30 form a heterojunction.

An “intrinsic semiconductor” in the present specification is not limited to a semiconductor completely intrinsic that does not include any conductivity-type impurity, but includes a semiconductor from which the inclusion of a conductivity-type impurity is intentionally prevented, and a semiconductor which includes a conductivity-type impurity that is being mixed during manufacturing processes and the like. Furthermore, when a small amount of a conductivity-type impurity is intentionally or unintentionally added, the intrinsic semiconductor includes a semiconductor which is formed such that the concentration of the conductivity-type impurity of the semiconductor is at most 5×10¹⁷ cm⁻³, for example. In addition, an “amorphous layer” in the present specification may include both an amorphous part and a crystalline part. Furthermore, when “substantially” can be expressed in a numerical value, the “substantially” means at least 95%.

The first conductivity type amorphous silicon layer 30n includes the first conductivity type impurity which is the same conductivity type impurity that the semiconductor substrate 20 includes. As the first conductivity type impurity, a dopant, such as phosphorus (P), arsenic (As), or antimony (Sb), is added to the first conductivity type amorphous silicon layer 30n. The concentration of the first conductivity type impurity in the first conductivity type amorphous silicon layer 30n is, for example, at least 5×10¹⁸ cm⁻³, and preferably 5×10²⁰ cm⁻³ to 5×10²¹ cm⁻³.

The first semiconductor layer 30 may be thick to an extent that carrier recombination at the first principal surface 21 of the semiconductor substrate 20 can be sufficiently reduced. On the other hand, the first semiconductor layer 30 may be thin to an extent that the amount of incident light which passivation layer 30 absorbs can be reduced as much as possible. The thickness of the first amorphous semiconductor layer 30a is approximately 2 nm to 75 nm, for example. More specifically, the thickness of the intrinsic amorphous silicon layer 30i is, for example, 1 nm to 25 nm, and preferably 2 nm to 5 nm. In addition, the thickness of the first conductivity type amorphous silicon layer 30n is, for example, 1 nm to 50 nm, and preferably 2 nm to 10 nm.

As illustrated in FIG. 1, the second semiconductor layer 40 of the second conductivity type which is a conductivity type different from the conductivity type that the semiconductor substrate 20 has is provided below the entirety of, or substantially the entirety of the second principal surface 22 of the semiconductor substrate 20. The second semiconductor layer 40 and the semiconductor substrate 20 join together to form a p-n junction. In this embodiment, an amorphous silicon layer 40a is used as the second semiconductor layer 40. In addition, the amorphous silicon layer 40a has a stacked structure in which an intrinsic amorphous silicon layer 40i and a second conductivity type amorphous silicon layer 40p of the second conductivity type are stacked from the second principal surface 22 of the semiconductor substrate 20 in the stated order. The intrinsic amorphous silicon layer 40i is provided below (the negative direction of the y axis) the second principal surface 22 of the semiconductor substrate 20. The second conductivity type amorphous silicon layer 40p is provided below (the negative direction of the y axis) the intrinsic amorphous silicon layer 40i. In the embodiment, the semiconductor substrate 20 and the second semiconductor layer 40 form a heterojunction.

The second conductivity type amorphous silicon layer 40p includes the second conductivity type impurity which is a different conductivity type impurity that the semiconductor substrate 20 includes. As the second conductivity type impurity, a dopant, such as boron (B) or aluminum (Al), is added to the second conductivity type amorphous silicon layer 40p. The concentration of the second conductivity type impurity in the second conductivity type amorphous silicon layer 40p is, for example, at least 1×10¹⁹ cm⁻³, and preferably about 5×10²⁰ cm⁻³ to 5×10²¹ cm⁻³.

The second semiconductor layer 40 may be thick to an extent that carrier recombination at the second principal surface 22 of the semiconductor substrate 20 can be sufficiently reduced. On the other hand, the second semiconductor layer 40 may be thin to an extent that the amount of resistance components which leads to power generation loss of the solar cell can be reduced as much as possible. The thickness of the second amorphous semiconductor layer 40a is approximately 2 nm to 75 nm, for example. More specifically, the thickness of the intrinsic amorphous silicon layer 40i is, for example, 1 nm to 25 nm, and preferably about 2 nm to 5 nm. In addition, the thickness of the second conductivity type amorphous silicon layer 40p is, for example, 1 nm to 50 nm, and preferably about 2 nm to 10 nm.

Note that, in order to improve the effect of reducing carrier recombination, each of the intrinsic amorphous silicon layers 30i and 40i, the first conductivity type amorphous silicon layer 30n, and the second conductivity type amorphous silicon layer 40p may contain hydrogen (H). In addition, each of the intrinsic amorphous silicon layers 30i and 40i, the first conductivity type amorphous silicon layer 30n, and the second conductivity type amorphous silicon layer 40p may contain, in addition to hydrogen (H), oxygen (O), carbon (C), or germanium (Ge).

Note that the first semiconductor layer 30 and the second semiconductor layer 40 are not limited to only the configurations described above. Each of the first semiconductor layer 30 and the second semiconductor layer 40 may be a semiconductor layer which has a conductivity type, and includes at least one of monocrystalline silicon, polycrystalline silicon, and the microcrystalline silicon. In addition, each of the first semiconductor layer 30 and the second semiconductor layer 40 may be a structure that includes the semiconductor layer, and an insulating layer which contains a silicon compound containing at least one of oxygen (O) and nitrogen (N), an aluminum compound containing at least one of oxygen (O) and nitrogen (N), or the like which are stacked in the stated order from the first principal surface 21 of the semiconductor substrate 20 or the second principal surface 22 of the semiconductor substrate 20. In the case of adopting this stacked structure, the insulating layer may be thick to a degree that allows a tunnel current to flow. For example, the thickness of the stacked structure is preferably 0.5 nm to 10 nm.

As illustrated in FIG. 1, the solar cell 10 includes a first electrode 50 and a second electrode 60. The first electrode 50 is provided above (the positive direction of the y axis) the first semiconductor layer 30, and is electrically connected with the first semiconductor layer 30. On the other hand, the second electrode 60 is provided below (the negative direction of the y axis) the second semiconductor layer 40, and is electrically connected with the second semiconductor layer 40.

In the embodiment, the first electrode 50 has a structure in which a first light-transmissive conductive film 50t and a first metal electrode 50m which is not light-transmissive are stacked in the stated order from the first semiconductor layer 30. The first light-transmissive conductive film 50t is provided above (the positive direction of the y axis) the first semiconductor layer 30. The first metal electrode 50m is provided above (the positive direction of the y axis) the first light-transmissive conductive film 50t. As illustrated in FIG. 2, the first metal electrode 50m includes a bus bar electrode 51m and a plurality of finger electrodes 52m. On the other hand, the second electrode 60 has a structure in which a second light-transmissive conductive film 60t and a second metal electrode 60m which is not light-transmissive are stacked in the stated order from the second semiconductor layer 40. The second light-transmissive conductive film 60t is provided below (the negative direction of the y axis) the second semiconductor layer 40. The second metal electrode 60m is provided below (the negative direction of the y axis) the second light-transmissive conductive film 60t. The second metal electrode 60m includes a bus bar electrode 61m and a plurality of finger electrodes 62m.

As illustrated in FIG. 1, the first light-transmissive conductive film 50t is provided above the entirety of, or substantially the entirety of the first semiconductor layer 30. In addition, the second light-transmissive conductive film 60t is provided below the entirety of, or substantially the entirety of the second semiconductor layer 40.

Each of the first light-transmissive conductive film 50t and the second light-transmissive conductive film 60t includes at least one of metallic oxides, such as indium oxide (In₂O₃), zinc oxide (ZnO), tin oxide (SnO₂), or titanium oxide (TiO₂), for example. In addition, an element, such as tin (Sn), zinc (Zn), tungsten (W), antimony (Sb), titanium (Ti), cerium (Ce), or gallium (Ga) may be added to the at least one of the metallic oxides. The thickness of each of the first light-transmissive conductive film 50t and the second light-transmissive conductive film 60t is, for example, 30 μm to 200 μm, and preferably 50 μm to 80 μm.

Each of the first metal electrode 50m and the second metal electrode 60m includes a metal, such as silver (Ag), copper (Cu), aluminum (Al), gold (Au), nickel (Ni), tin (Sn), or chromium (Cr), or an alloy including at least one of these metals, for example. Each of the first metal electrode 50m and the second metal electrode 60m may be formed of a single layer or multiple layers.

A bus bar electrode 51m and a bus bar electrode 61m are electrically connected with the plurality of finger electrodes 52m and the plurality of finger electrodes 62m, respectively, and are disposed to intersect with the plurality of finger electrodes 52m and the plurality of finger electrodes 62m, respectively. In the embodiment, the solar cell 10 includes a plurality of bus bar electrodes 51m and a plurality of bus bar electrodes 61m which are linear electrodes, for example. In addition, the plurality of finger electrodes 52m and the plurality of finger electrodes 62m are narrow linear electrodes each of which is disposed next to each other in parallel, for example. Note that the first metal electrode 50m and the second metal electrode 60m need not include a bus bar electrode 51m and a bus bar electrode 61m, respectively. The thickness of a bus bar electrode 51m, a bus bar electrode 61m, a finger electrode 52m, and a finger electrode 62m is, for example, 10 μm to 50 μm. The width of a bus bar electrode 51m and a bus bar electrode 61m is, for example, 100 μm to 2 m, and the width of a finger electrode 52m and a finger electrode 62m is, for example, 30 μm to 300 μm.

In the embodiment, as illustrated in FIG. 2, the finger electrodes 52m and 62m are provided such that they extend in the x direction that is the same direction as the direction of the long axis 23. In other words, the finger electrodes 52m and 62m are provided such that they extend in parallel to a side formed by two pyramidal surfaces 26 and 27. In addition, the finger electrodes 52m and 62m are provided such that they extend in parallel to a side formed by two pyramidal surfaces 28 and 29. It is known that the bleeding of a collection electrode, such as a finger electrode, reduces as the bumpy portions that form a texture structure downsize. Accordingly, it is possible to prevent the bleeding of the finger electrodes 52m and 62m.

### [2. Effects, etc.]

The solar cell 10 according to an aspect of the present invention includes the semiconductor substrate 20 having the first principal surface 21 at an angle of at least 1 degree and at most 45 degrees relative to a plane orientation. The first principal surface 21 is in a shape of a rectangle having the long axis 23 and the short axis 24 orthogonal to each other.

Accordingly, it is possible to provide the solar cell 10 having an improved power generation characteristic.

In addition, the semiconductor substrate 20 is a monocrystalline silicon substrate. The plane orientation mentioned above is a (100) plane. The first principal surface 21 may be at an angle of at least 2 degrees and at most 20 degrees relative to the (100) plane.

Furthermore, the semiconductor substrate 20 includes bumpy portions two-dimensionally arrayed on the first principal surface 21. The bumpy portions each are in the shape of a quadrangular pyramid formed to expose (111) planes of the semiconductor substrate 20. The quadrangular pyramid has two first pyramidal surfaces 26 and 27 adjoining each other and two second pyramidal surfaces 28 and 29 adjoining each other, and the area of each of the two first pyramidal surfaces 26 and 27 may be larger than the area of each of the two second pyramidal surfaces 28 and 29.

Moreover, a cross section of the semiconductor substrate 20 may be in the shape of a parallelogram. The cross section is perpendicular to the first principal surface 21 and parallel to the long axis 23.

### [3. Manufacturing Method of Solar Cell According to Embodiment]

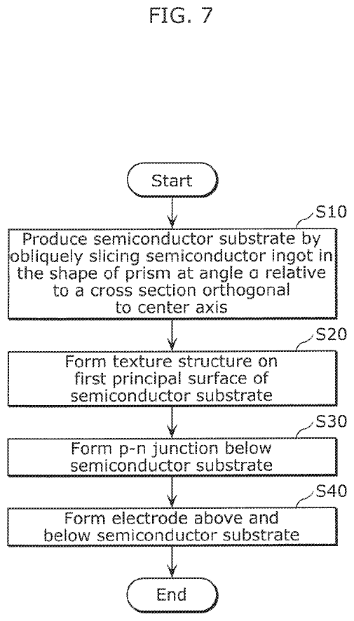

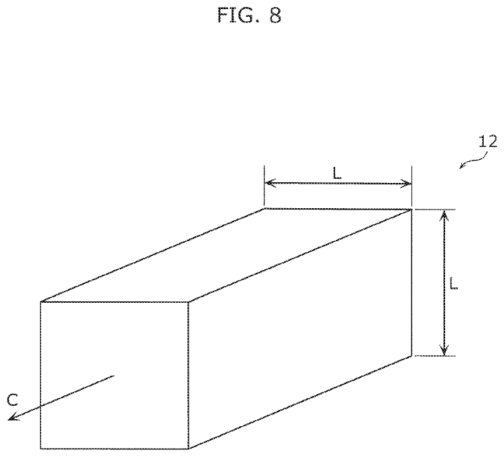

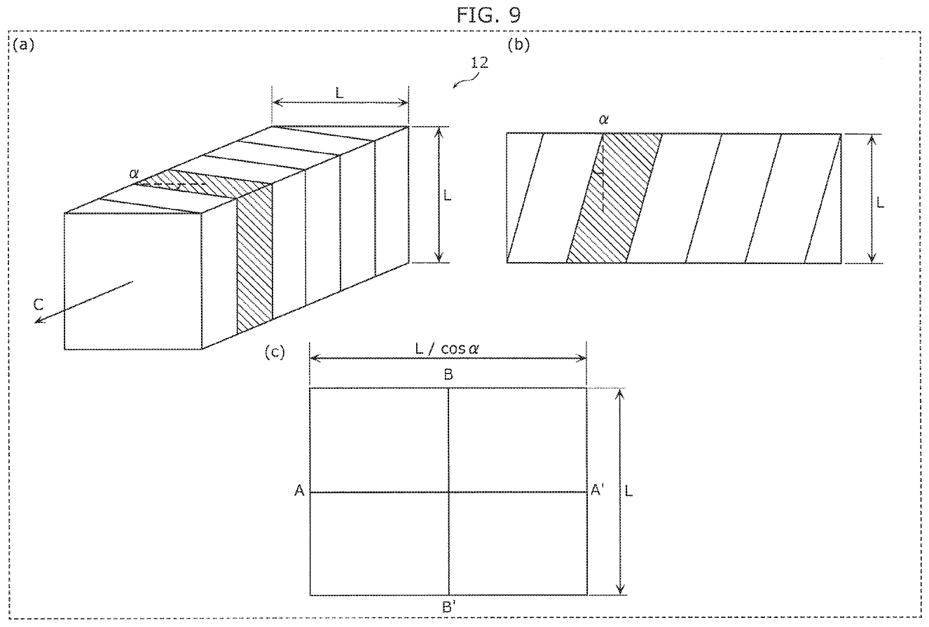

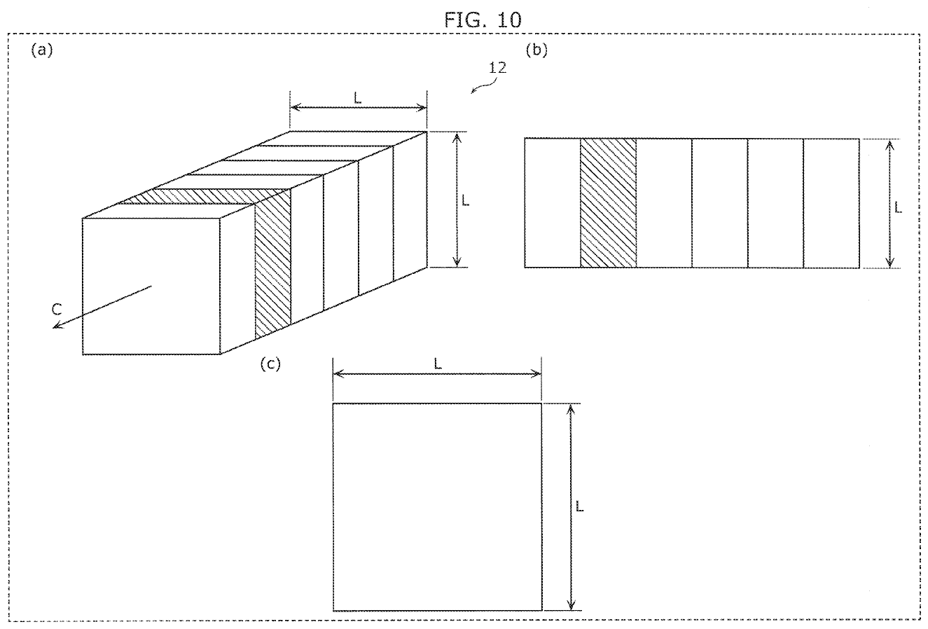

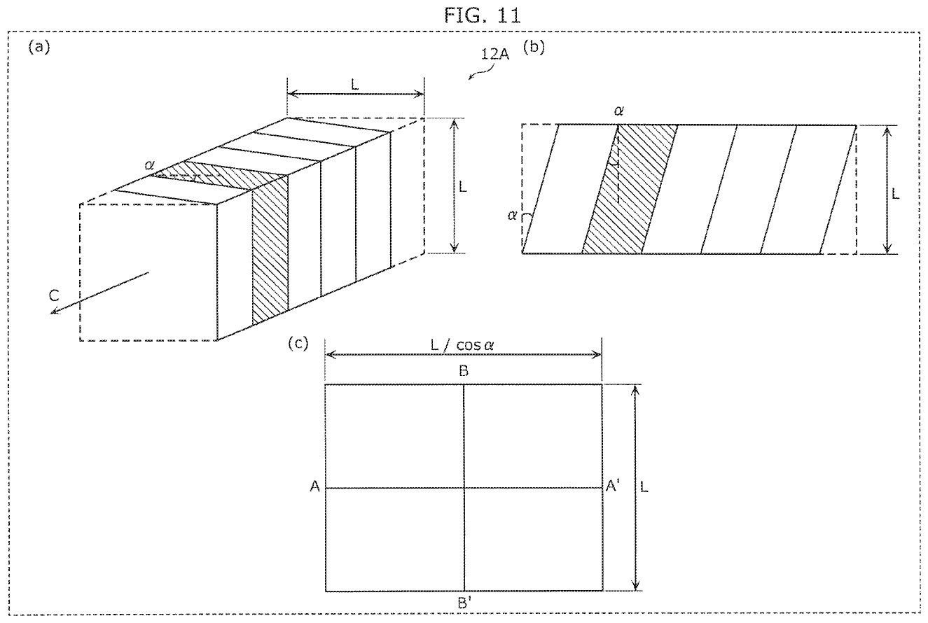

A manufacturing method of the solar cell 10 according to the embodiment will be described with reference to FIG. 7 through FIG. 11. FIG. 7 is a flowchart illustrating a manufacturing method of the solar cell 10 according to the embodiment. FIG. 8 is a perspective view illustrating the appearance of a semiconductor ingot 12 according to the embodiment. FIG. 9 is a diagram illustrating a process of slicing the semiconductor ingot 12 according to the embodiment. FIG. 10 is a diagram illustrating a process of slicing the semiconductor ingot 12 according to a conventional example. FIG. 11 is a diagram illustrating a process of slicing a semiconductor ingot 12A according to a variation of the embodiment.

First, as illustrated in FIG. 8, a semiconductor ingot 12 in the shape of a prism is prepared. In the embodiment, a monocrystalline silicon ingot in the shape of a right prism is used as the semiconductor ingot 12. In addition, a cross section orthogonal to the center axis C of the semiconductor ingot 12 in the shape of the right prism is a (100) plane. The cross section orthogonal to the center axis C of the semiconductor ingot 12 has a substantially square shape, and the length of a side of the cross section is represented by L. The substantially square shape includes a square, an octagon formed out of the square of which the four corners are cut, and the octagon with rounded cut-outs.

Next, as illustrated in part (a) and part (b) in FIG. 9, the semiconductor ingot 12 is obliquely sliced by the angle α relative to a cross section orthogonal to the center axis C (S10). Part (a) in FIG. 9 illustrates a perspective view of the semiconductor ingot 12 which has been sliced. Part (b) in FIG. 9 illustrates a plan view of the top face of the semiconductor ingot 12 which has been sliced. Part (c) in FIG. 9 illustrates a plan view of a semiconductor substrate produced from the semiconductor ingot 12 by slicing the semiconductor ingot 12. The angle α is, for example, at least 1 degree and at most 45 degrees, and preferably, at least 2 degrees and at most 20 degrees. More preferably, the angle α is at least 3 degrees and at most 10 degrees. In the embodiment, the semiconductor ingot 12 is sliced using a wire saw. As a result, in comparison with the case in which the semiconductor ingot 12 is sliced in parallel with the cross section orthogonal to the center axis C using a conventional technology as illustrated in part (a) through part (c) in FIG. 10, it is possible to obtain a semiconductor substrate 20 which has the first principal surface 21 and the second principal surface 22 each having a larger area. As illustrated in part (c) in FIG. 9, when the semiconductor ingot 12 is obliquely sliced by the angle α, the length of a line segment from B to B′ is represented by L, and the length of a line segment from A to A′ is expressed by L/cos α. Thus, by obliquely slicing the semiconductor ingot 12 by the angle α, it is possible to obtain semiconductor substrates 20 each having a larger area. The use of this semiconductor substrate 20 having a larger area can improve the power generation characteristic of a solar cell 10 and a solar cell module 11 that uses the solar cell 10. In addition, if the angle α is too small, it is unlikely to expect higher improvement in the power generation characteristic, and if the angle α is too large, it is likely that the number of excessive fragments of a semiconductor ingot which cannot be used for a solar cell will be produced. Therefore, it is also preferable that the angle α to be in the range of at least 5 degrees and at most 30 degrees.

Note that as illustrated in part (a) and part (b) in FIG. 11, a semiconductor ingot 12A according to a variation need not be in the shape of a rectangular prism (see part (a) and part (b) in FIG. 9), but may have a surface slanted by the angle α relative to a cross section orthogonal to the center axis C. As illustrated in part (a) and part (b) in FIG. 11, the obliquely slicing of the semiconductor ingot 12A by the angle α relative to a cross section orthogonal to the center axis C hardly produces unnecessary fragments from the semiconductor ingot 12A, and thus the workability is improved.

Next, the semiconductor substrate 20 which is produced in step S10 is anisotropically etched. With this, a texture (bumpy portions) structure in which quadrangular pyramids each of which having (111) planes as slopes are two-dimensionally arrayed is formed on the first principal surface 21 of the semiconductor substrate 20 and the second principal surface 22 of the semiconductor substrate 20 (S20).

Specifically, the semiconductor substrate 20 is immersed in an anisotropic etching solution to begin with. The anisotropic etching solution is an alkaline aqueous solution which includes, for example, at least one of sodium hydroxide (NaOH), potassium hydroxide (KOH), and tetramethylammonium hydroxide (TMAH). By immersing a surface that forms the angle α with a (100) plane of the semiconductor substrate 20, the first principal surface 21 of the semiconductor substrate 20 and the second principal surface 22 of the semiconductor substrate 20 are anisotropically etched along the (111) planes. Here, the angle α that forms an angle with the (100) plane of the semiconductor substrate 20 is preferably at least 2 degrees and at most 20 degrees, considering the manufacturability of the anisotropic etching.

Consequently, the ridged structure in which the quadrangular pyramids are two-dimensionally arrayed is formed on each of the first principal surface 21 of the semiconductor substrate 20 and the second principal surface 22 of the semiconductor substrate 20 as described above. The forming of the texture structures which reflect and diffract light in mutually opposite directions each on the first principal surface 21 of the semiconductor substrate 20 and the second principal surface 22 of the semiconductor substrate 20 allows light which enters the solar cell 10 to be more complexly reflected and diffracted, thereby improving the efficiency of utilizing the light which enters the solar cell 10. Consequently, it is possible to improve the power generation characteristic of the solar cell 10.

Next, the semiconductor substrate 20 is immersed in an isotropic etching solution. The peaks and the troughs of bumpy portions which form the texture structures are processed into the shape of an R. The isotropic etching solution is, for example, a mixed solution of hydrofluoric acid (HF) and nitric acid (HNO₃), or a mixed solution of hydrofluoric acid (HF), nitric acid (HNO₃), and acetic acid (CH₃COOH).

Next, the amorphous silicon layer 30a and the amorphous silicon layer 40a are formed on the first principal surface 21 of the semiconductor substrate 20 and the second principal surface 22 of the semiconductor substrate 20, respectively. The amorphous silicon layers 30a and 40a can be formed using a chemical vapor deposition (CVD) method and the like which is exemplified in the plasma CVD method, for example. The intrinsic amorphous silicon layer 30i can be formed using source gas which is silane (SiH₄) diluted with hydrogen (H₂). The first conductivity type amorphous silicon layer 30n can be formed using source gas which is silane (SiH₄) to which phosphine (PH₃) is added, and then diluted with hydrogen (H₂). The second conductivity type amorphous silicon layer 40p can be formed using source gas which is silane (SiH₄) to which diborane (B₂H₆) is added, and then diluted with hydrogen (H₂). In this way, a p-n junction is formed on the semiconductor substrate 20.

Next, the first light-transmissive conductive film 50t and the second light-transmissive conductive film 60t are formed on the amorphous silicon layer 30a and the amorphous silicon layer 40a, respectively. The first light-transmissive conductive film 50t and the second light-transmissive conductive film 60t can be formed using a sputtering method, a vacuum evaporation method, a CVD method, or the like.

Next, the first metal electrode 50m and the second metal electrode 60m are formed on the first light-transmissive conductive film 50t and the second light-transmissive conductive film 60t, respectively. The first metal electrode 50m and the second metal electrode 60m can be formed using, for example, a screen printing method that uses a conductive paste, such as an Ag paste. The first metal electrode 50m and the second metal electrode 60m are formed by drying or sintering the conductive paste after the conductive paste is arranged using the screen printing method. In addition, the first metal electrode 50m and the second metal electrode 60m can be formed using an electrolytic plating method or a vacuum evaporation method. In this way, the electrodes are formed on the semiconductor substrate 20 (S40).

A manufacturing method of the solar cell according to an aspect of the present invention includes: (i) a process of producing a semiconductor substrate by obliquely slicing a semiconductor ingot in the shape of a prism at an angle of at least 1 degree and at most 45 degrees relative to a cross section orthogonal to the center axis of the semiconductor ingot; and (ii) a process of forming a texture structure on the first principal surface of the semiconductor substrate.

In this way, compared to a semiconductor produced by slicing a semiconductor ingot at an angle orthogonal to the center axis of the semiconductor ingot, a semiconductor substrate having the first principal surface and the second principal surface each having a larger area can be obtained. Therefore, it is possible to manufacture the solar cell 10 having an improved power generation characteristic.

### [4. Configuration of Solar Cell Module According to Embodiment]

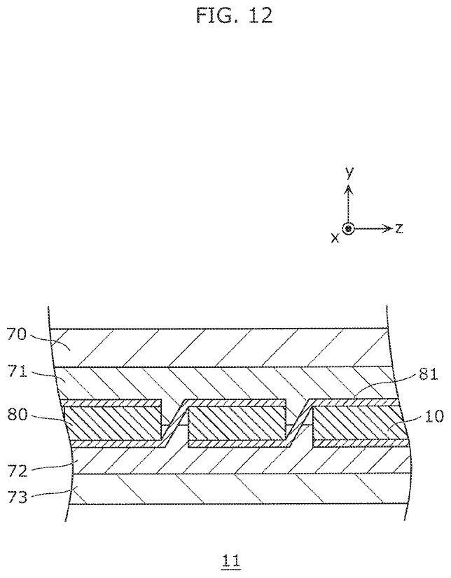

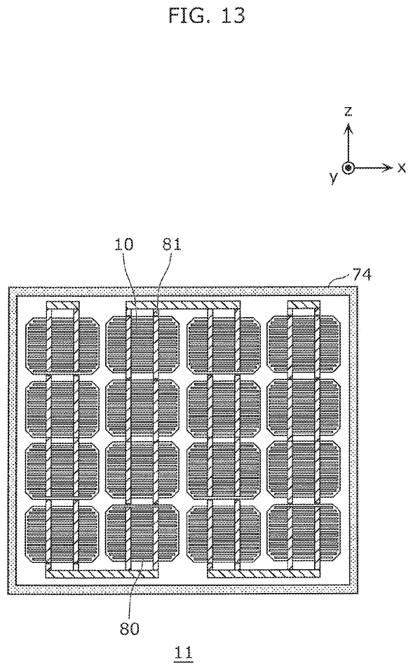

A general configuration of the solar cell module 11 according to the embodiment will be described with reference to FIG. 12 and FIG. 13.

FIG. 12 is a cross sectional view illustrating a structure of the solar cell module 11 according to the embodiment. FIG. 13 is a plan view of the solar cell module 11 according to the embodiment, viewed from the light receiving surface-side of the solar cell module 11.

As illustrated in FIG. 12, the solar cell module 11 has a stacked structure in which a first protective material 70, a first sealing medium 71, a solar cell string 80, a second sealing medium 72, and a second protective material 73 are stacked in the stated order. In addition, as illustrated in FIG. 13, the solar cell module 11 is enclosed with a frame 74.

The first protective material 70 is disposed on the light receiving surface-side of the solar cell string 80. In addition, the second protective material 73 is disposed on the back surface-side of the solar cell string 80. That is, the solar cell string 80 is disposed between the first protective material 70 and the second protective material 73. The first protective material 70 may be formed of a material which has high light transmittance, and is hard enough to be able to protect the light receiving surface of the solar cell module 11 from a falling object and the like. For example, a resin material, such as glass or acrylic, is used for the first protective material 70. Like the first protective material 70, the second protective material 73 may be formed of a resin material, such as glass or acrylic. Also, a composite resin sheet having high weather resistance may be used for the second protective material 73. Furthermore, an opaque board-like object and a reflective film can also be used for the second protective material 73 to prevent the light that passes through the second sealing medium 72 from exiting through the second protective material 73. For example, a laminated film, such as a resin film in which aluminum foil is included, can be used.

The first sealing medium 71 is disposed on the light receiving surface-side of the solar cell string 80. In addition, the second sealing medium 72 is disposed on the back surface-side of the solar cell string 80. That is, the solar cell string 80 is disposed between the first sealing medium 71 and the second sealing medium 72. For the first sealing medium 71, a light-transmissive material can be used. For example, an ethylene-vinyl acetate copolymer (EVA) is used for the first sealing medium 71. In addition, a material for the first sealing medium 71 may be selected from a thermoplastic resin, such as polyolefins, polyethylenes, polyphenylenes, and a copolymer of the above, or a group consisting of thermosetting resins. Like the first sealing medium 71, a light-transmissive material can be used for the second sealing medium 72. In this case, the same material used for the first sealing medium 71 can be used for the second sealing medium 72. In addition, a colored material may be used for the second sealing medium 72. As the colored material, the above sealing medium including a light-transmissive material to which an inorganic pigment, such as titanium oxide or zinc oxide, is added as an additive to color the light-transmissive material in white can be used. The first sealing medium 71 and the second sealing medium 72 prevent the ingress of moisture and the like into the solar cell string 80 which has a function of electric power generation, and improve the strength of the entire solar cell module 11.

As illustrated in FIG. 13, one solar cell string 80 includes four solar cells 10 which are connected to one another in series with a wiring component 81 along the z direction. A group of solar cell strings includes four solar cell strings 80 disposed along the x direction, and the four solar cell strings 80 are connected to one another in series with a connecting wiring component. That is to say, the group of solar cell strings includes 16 solar cells 10 (4×4) which are connected in series.

Two adjacent solar cells 10 are connected by a wiring component 81 which connects the bus bar electrode 51m disposed on the light receiving surface-side of one solar cell 10 and the bus bar electrode 52m disposed on the back surface-side of the other solar cell 10.

The solar cell string 80 includes a plurality of solar cells 10 which are electrically connected in series with a wiring component 81. The wiring component 81 includes a metal, such as copper, aluminum, silver, nickel, and gold, or an alloy including at least one of these metals, for example. The wiring component 81 may include a metal coated with solder.

A solar cell module according to an aspect the present invention includes a semiconductor substrate having a first principal surface at the angle of at least 1 degree and at most 45 degrees relative to a plane orientation. The first principal surface is in a shape of a rectangle having a long axis and a short axis orthogonal to each other.

Accordingly, it is possible to provide a solar cell module having an improved power generation characteristic.

### Other Embodiment

The foregoing has described, based on the embodiments described above, the solar cell according to an aspect of the present invention, and the solar cell module according to an aspect of the present invention, yet the present invention is not limited to such embodiments.

For example, an aspect of the present invention encompasses (i) embodiments obtained by applying various modifications which may be conceived by a person skilled in the art to the embodiments described above, and (ii) embodiments achieved by optionally combining elements and functions in the embodiments described above without departing from the scope of the present invention.

While the foregoing has described one or more embodiments and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

1. A solar cell, comprising:
a semiconductor substrate having a first principal surface at an angle of at least 1 degree and at most 45 degrees relative to a plane orientation, wherein
the first principal surface is in a shape of a rectangle having a long axis and a short axis orthogonal to each other.

2. The solar cell according to claim 1, wherein
the semiconductor substrate is a monocrystalline silicon substrate,
the plane orientation is a (100) plane, and
the first principal surface is at an angle of at least 2 degrees and at most 20 degrees relative to the (100) plane.

3. The solar cell according to claim 2, wherein
the semiconductor substrate includes bumpy portions two-dimensionally arrayed on the first principal surface,
the bumpy portions each are in a shape of a quadrangular pyramid formed to expose (111) planes of the semiconductor substrate,
the quadrangular pyramid has two first pyramidal surfaces adjoining each other and two second pyramidal surfaces adjoining each other, and
an area of each of the two first pyramidal surfaces is larger than an area of each of the two second pyramidal surfaces.

4. The solar cell according to claim 1, wherein
a cross section of the semiconductor substrate is in a shape of a parallelogram, the cross section being perpendicular to the first principal surface and parallel to the long axis.

5. A solar cell module, comprising:
the solar cell according to claim 1.
